(19) United States
(12) Patent Application Publication
(10) Pub. No.: US 2010/0090749 A1
(43) Pub. Date: Apr. 15, 2010

(54) MULTI-FUNCTION CHIP

(75) Inventor: Chin-Sheng Yang, Hsinchu (TW)

Correspondence Address: NORTH AMERICA INTELLECTUAL PROPERTY CORPORATION, P.O. BOX 506, MERRIFIELD, VA, 22116, US

(73) Assignee: UNITED MICROELECTRONICS CORP., Hsinchu (TW)

(21) Appl. No.: 12/248,580

(22) Filed: Oct. 9, 2008

(51) Int. Cl. H03H 11/00

(52) U.S. Cl. 327/524

(57) ABSTRACT

A multi-function chip including a circuit and at least one control circuit is provided. The circuit having multiple functions includes an interconnection. The interconnection has at least one resistance-variable segment. The control circuit is electronically connected to the resistance-variable segment. One of the functions is carried out by adjusting the resistance of the resistance-variable segment with the control circuit.

### BACKGROUND OF THE INVENTION

1. Field of the Invention

The present invention is related to a chip, and more generally to a multi-function chip of which the function(s) can be switched.

2. Description of Related Art

With the rapid advance of electronic technology, various electronic products are developed to have multiple functions instead of a single function and are widely applied in our daily life and work.

Currently, a commercially available electronic product, such as a mobile phone or a flash disk, is usually provided with other functions in addition to the main function. For example, in addition to the main communication function, a mobile phone is further provided with camera, radio, game, and audio recorder functions. Typically, these functions are achieved by different chips and the chips with different functions occupy a considerable volume in an electronic product, so that the dimension of the electronic product cannot be reduced.

Further, if the above-mentioned functions are required to integrate into one chip, only a programmable logic device (PLD) chip can achieve this purpose. However, in the so-called PLD chip, only a certain function is burned inside by the software, and the burned function cannot be switched. Therefore, the requirement of using different functions anytime is hardly met when the PLD chip is applied to the multi-function electronic product.

### SUMMARY OF THE INVENTION

Accordingly, the present invention provides a multi-function chip having a plurality of switchable and reversible functions.

The present invention further provides a multi-function chip of which various functions can be carried out by adjusting the resistance of the resistance-variable segment.

The present invention provides a multi-function chip including a circuit and at least one control circuit. The circuit having multiple functions includes an interconnection. The interconnection has at least one resistance-variable segment. The control circuit is electronically connected to the resistance-variable segment. One of the functions is carried out by adjusting the resistance of the resistance-variable segment with the control circuit.

According to an embodiment of the present invention, the resistance-variable segment includes a giant magnetoresistance (GMR) material or a phase change material, for example.

According to an embodiment of the present invention, the resistance-variable segment includes an entire conductive line, a portion of a conductive line, an entire plug, or a portion of a plug.

According to an embodiment of the present invention, the resistance-variable segment is a portion of a fuse.

According to an embodiment of the present invention, the fuse is a copper fuse, an aluminum fuse, or an electronic fuse, for example.

According to an embodiment of the present invention, variance of the resistance of the at least one resistance-variable segment is reversible.

The present invention further provides a multi-function chip including a first circuit having a first function, a second circuit having a second function and at least one control circuit. The first circuit and the second circuit share at least one semiconductor device and a portion of an interconnection, and the portion of the interconnection has at least one resistance-variable segment. The control circuit is electronically connected to the resistance-variable segment. The first function or the second function is carried out by adjusting the resistance of the resistance-variable segment with the control circuit.

In the present invention, a resistance-variable segment is formed in an interconnection electronically connected to a multi-function circuit, and the resistance of the resistance-variable segment is adjusted by a control circuit. Therefore, by controlling the segment to be conductive or not to further change the wiring of the interconnection, one of the functions can be carried out and the function in use can be switched to any of the functions.

Further, the multi-function chip can be a chip having a plurality of circuits with different functions and the circuits share at least one semiconductor device and a portion of an interconnection. The portion of the interconnection has a resistance-variable segment, so that various functions can be carried out by adjusting the resistance of the resistance-variable segment with a control circuit.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view illustrating a multi-function chip according to an embodiment of the present invention.

FIG. 2 illustrates a diagram of resistance as a function of pulse width of a resistance-variable material according to an embodiment of the present invention.

FIGS. 3A-3E are respective schematic views of interconnections each having a segment of which the resistance is variable and reversible according to an embodiment of the present invention.

FIG. 4 is a schematic view of the function switch of a multi-function chip according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

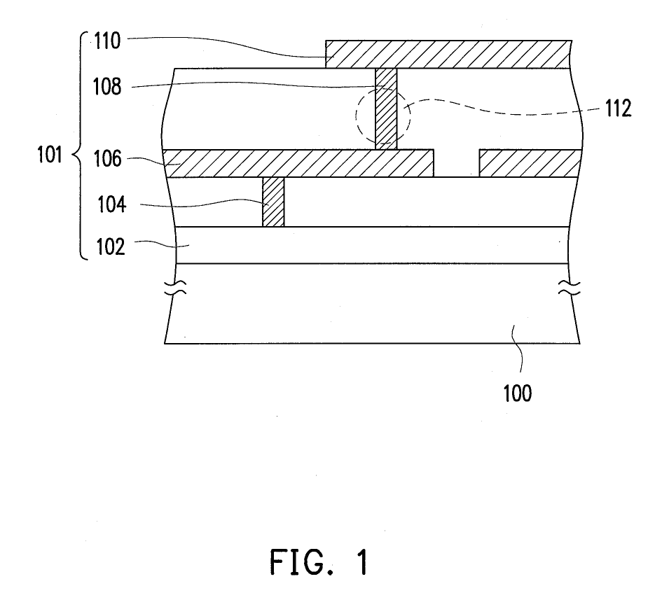

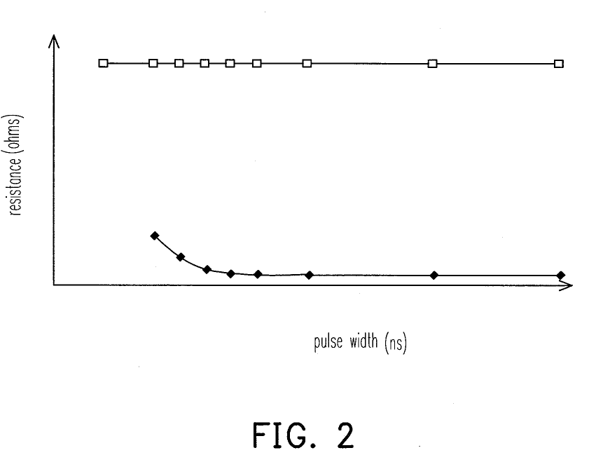

FIG. 1 is a schematic cross-sectional view illustrating a multi-function chip according to an embodiment of the present invention. Referring to FIG. 1, a chip 100 includes a circuit 101 and a control circuit (not shown). The circuit 101 has a first function and a second function, for example. The circuit 101 includes a semiconductor device 102 and an interconnection electronically connected to the semiconductor device 102. The interconnection has at least one resistance-variable segment. The resistance-variable segment includes a giant magnetoresistance (GMR) material or a phase change material, for example. As shown in FIG. 2, the above-mentioned materials have different resistances under different conditions, so the current path can be controlled to be formed or not by adjusting the resistances. The semiconductor device 102 is a metal-oxide-semiconductor (MOS) transistor, a memory or other suitable devices, for example.

In this embodiment, the interconnection includes a plug 104, a first-layer conductive line 106, a plug 108 and a second-layer conductive line 110, and a segment 112 in the plug 108 is a resistance-variable segment. The control circuit is electronically connected to the segment 112, and the plug 108 is controlled to be conductive or not by changing the resistance of the segment 112. In details, when the segment 112 is adjusted to have a low resistance by the control circuit, the second-line conductive line 110 is electronically connected to the first-layer conductive line 106 via the plug 108, so as to carry out the first function of the circuit 101. When the segment 112 is adjusted to have a high resistance by the control circuit, an open circuit exists between the second-line conductive line 110 and the first-layer conductive line 106, so as to carry out the second function of the circuit 101. Preferably, the resistance of the segment 112 is variable and reversible, so that the user can use the control circuit to adjust the plug 108 to be conductive or not upon the actual requirement, and the function of the chip 100 can be switched between the first function and the second function many times.

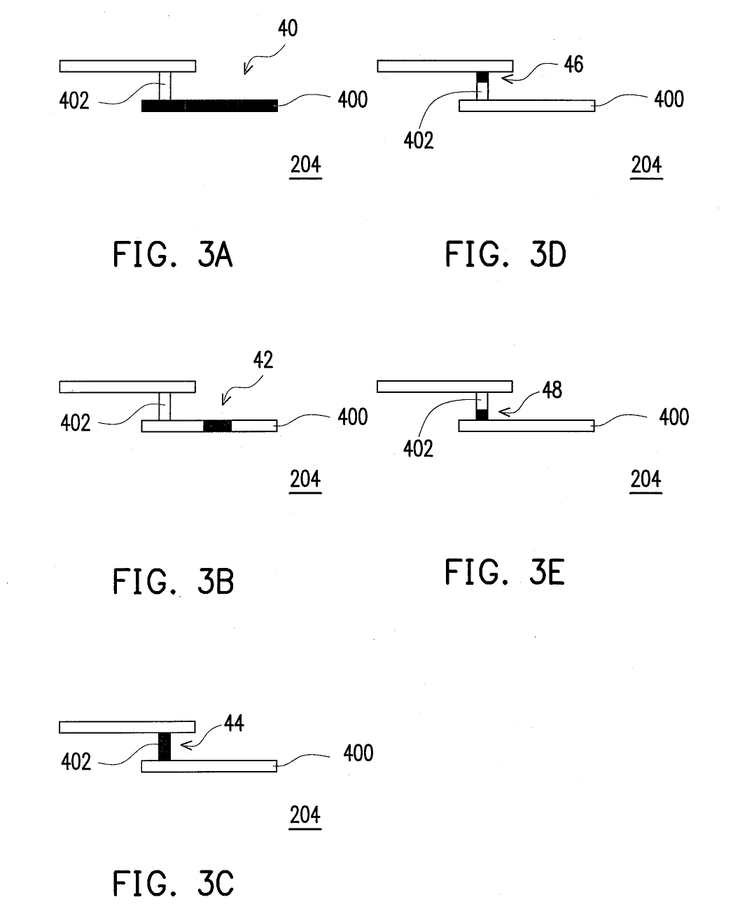

It is noted that, in this embodiment, the segment 112 is disposed in the middle part of the plug 108. However, in other embodiments, the resistance-variable segment can be an entire conductive line, a portion of a conductive line, an entire plug or a portion a plug. As shown in FIG. 3A, the interconnection 204 has a conductive line 400 and a plug 402, and the resistance-variable segment 40 is the entire conductive line 400. As shown in FIG. 3B, the resistance-variable segment 42 is a portion of the conductive line 400. As shown in FIG. 3C, the resistance-variable segment 44 is the entire plug 402. As shown in FIG. 3D, the resistance-variable segment 46 is at the top of the plug 402. As shown in FIG. 3E, the resistance-variable segment 48 is at the bottom of the plug 402. Further, the resistance-variable segment can be a portion of the fuse of the interconnection. The fuse can be a copper fuse, an aluminum fuse or an electronic fuse (e-fuse), for example.

In this embodiment, the interconnection has a resistance-variable segment, so that the user can use the control circuit to adjust the resistance of the segment, thereby controlling the current paths of the circuit to switch the function of the chip 100 between the first function and the second function. In another embodiment, if the circuit structure is more complicated, the interconnection can have a plurality of resistance-variable segments, and the user can use one or more control circuits to adjust the resistances of these segments, thereby switching the function of the chip 100 between the first function and the second function. Further, when the circuit of the chip has three or more functions, a plurality of resistance-variable segments are required to form in the interconnection, so that the user can use one or more control circuits to adjust the resistances of these segments, thereby switching the chip between functions.

The function switch of the multi-function chip of the present invention is illustrated below by exemplifying a multi-function chip with two functions.

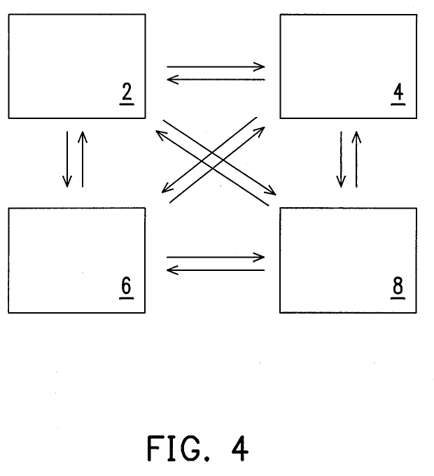

FIG. 4 is a schematic view of the function switch of a multi-function chip according to an embodiment of the present invention. Referring to FIG. 4, when the chip is in a status 2, the chip can carry out the first function and the second function simultaneously. When the user desires to switch the chip from the status 2 to a status 4 in which only the first function is carried out, the user can use the control circuit to adjust the resistance of the resistance-variable segment in the interconnection to turn off the second function. Similarly, when the user desires to switch the chip from the status 2 to a status 6 in which only the second function is carried out, the user can use the control circuit to adjust the resistance of the resistance-variable segment to turn off the first function. Similarly, the user can use the control circuit to adjust the resistance of the resistance-variable segment to turn off the first function and the second function simultaneously, so as to switch the chip from the status 2 to a status 8. When variance of the resistance of the resistance-variable segment is reversible, the user can use the control circuit to adjust the resistance of the resistance-variable segment, and thus, the chip can be switched among statuses 2, 4, 6 and 8, and the status switch can be performed repeatedly.

It is noted that the above-mentioned method, in which the function(s) of the chip can be switched by the resistance of the resistance-variable segment, can be applied to not only a multi-function chip having a multi-function circuit, but also a multi-function chip having a plurality of circuits with different functions.

In detail, the multi-function chip includes a first circuit, a second circuit and at least one control circuit. The first circuit has the first function, and the second circuit has the second function. Further, the first circuit and the second circuit share at least one semiconductor device (such as a MOS transistor) and a portion of the interconnection. The portion of the interconnection has at least one resistance-variable segment. Preferably, variance of the resistance of the resistance-variable segment is reversible. A control circuit is electronically connected to one or more resistance-variable segments. Therefore, the first function or the second function can be carried out by adjusting the resistance of the resistance-variable segment with the control circuit, and the first function and the second function can be switched.

In addition, except the first circuit having the first function and the second circuit having the second function, the multi-function chip can further includes a plurality of circuits having different functions. It is noted that these circuits are required to share at least one semiconductor device and a portion of the interconnection.

In summary, the multi-function chip of the present invention includes a circuit having different functions, and the interconnection electronically connected to the circuit has a resistance-variable segment. The resistance of the resistance-variable segment can be adjusted by the control circuit electronically connected to resistance-variable segment, and thus, one of the functions can be carried out by controlling the resistance-variable segment to be conductive or not to further change the wiring of the interconnection, and the function is use can be switched to any of the functions.

Further, the multi-function chip can include a plurality of circuits with different functions and these circuits share at least one semiconductor device and a portion of an interconnection. The portion of the interconnection has a resistance-variable segment, so that various functions can be carried out by controlling the resistance of the resistance-variable segment with the control circuit.

In addition, when the multi-function chip of the present invention is applied to an electronic product, the purpose of reducing the dimension of the electronic product is achieved, and the requirement of using different functions anytime is met.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A multi-function chip, comprising:
a circuit, having multiple functions and comprising an interconnection, wherein the interconnection has at least one resistance-variable segment; and
at least one control circuit, electronically connected to the at least one resistance-variable segment, wherein one of the functions is carried out by adjusting a resistance of the resistance-variable segment with the control circuit.

2. The multi-function chip of claim 1, wherein the at least one resistance-variable segment comprises a giant magnetoresistance (GMR) material or a phase change material.

3. The multi-function chip of claim 1, wherein the at least one resistance-variable segment comprises an entire plug.

4. The multi-function chip of claim 1, wherein the resistance-variable segment is a portion of a fuse.

5. The multi-function chip of claim 4, wherein the fuse is a copper fuse, an aluminum fuse, or an electronic fuse.

6. The multi-function chip of claim 1, wherein variance of the resistance of the at least one resistance-variable segment is reversible.

7. A multi-function chip, comprising:
a first circuit, having a first function;
a second circuit, having a second function, wherein the first circuit and the second circuit share at least one semiconductor device and a portion of an interconnection, and the portion of the interconnection has at least one resistance-variable segment; and
at least one control circuit, electronically connected to the at least one resistance-variable segment, wherein the first function or the second function is carried out by adjusting a resistance of the resistance-variable segment with the control circuit.

8. The multi-function chip of claim 7, wherein the at least one resistance-variable segment comprises a GMR material or a phase change material.

9. The multi-function chip of claim 7, wherein the at least one resistance-variable segment comprises an entire plug.

10. The multi-function chip of claim 7, wherein the resistance-variable segment is a portion of a fuse.

11. The multi-function chip of claim 10, wherein the fuse is a copper fuse, an aluminum fuse, or an electronic fuse.

12. The multi-function chip of claim 7, wherein variance of the resistance of the at least one resistance-variable segment is reversible.

13. The multi-function chip of claim 1, wherein the at least one resistance-variable segment comprises an entire conductive line.

14. The multi-function chip of claim 1, wherein the at least one resistance-variable segment comprises a portion of a conductive line.

15. The multi-function chip of claim 1, wherein the at least one resistance-variable segment comprises a portion of a plug.

16. The multi-function chip of claim 7, wherein the at least one resistance-variable segment comprises an entire conductive line.

17. The multi-function chip of claim 7, wherein the at least one resistance-variable segment comprises a portion of a conductive line.

18. The multi-function chip of claim 7, wherein the at least one resistance-variable segment comprises a portion of a plug.
